(19) United States
(12) Patent Application Publication
(10) Pub. No.: US 2013/0247960 A1
(43) Pub. Date: Sep. 26, 2013

(54) SOLAR-LIGHT CONCENTRATION APPARATUS

(71) Applicant: MORGAN SOLAR INC., Toronto (CA)

(72) Inventor: John Paul MORGAN, Toronto (CA)

(73) Assignee: MORGAN SOLAR INC., Toronto (CA)

(21) Appl. No.: 13/892,821

(22) Filed: May 13, 2013

Related U.S. Application Data
(63) Continuation of application No. 13/053,184, filed on Mar. 21, 2011.
Application No. 13/053,184 is a continuation-in-part of application No. 13/028,957, filed on Feb. 16, 2011.
Application No. 13/028,957 is a continuation of application No. 13/007,910, filed on Jan. 17, 2011, now Pat. No. 7,991,261.
Application No. 13/007,910 is a continuation of application No. 12/113,705, filed on May 1, 2008, now Pat. No. 7,873,257.
(60) Provisional application No. 61/315,744, filed on Mar. 19, 2010.
(60) Provisional application No. 60/915,207, filed on May 1, 2007.
(60) Provisional application No. 60/942,745, filed on Jun. 8, 2007.
(60) Provisional application No. 60/951,775, filed on Jul. 25, 2007.

(51) Int. Cl. H01L 31/052

(52) U.S. Cl. CPC H01L 31/0522
USPC 136/246; 136/259

(57) ABSTRACT

A photovoltaic solar-light concentration apparatus comprises a focusing layer having a plurality of focusing elements disposed adjacent to each other. A waveguide optically coupled and separated from the focusing layer has an exit surface and a plurality of deflecting elements. Each of the deflecting elements receives a band shaped solar-light beam from a corresponding focusing element. The deflecting elements are shaped and disposed so as to deflect and trap the solar-light beams inside the waveguide at an angle that insures total internal reflection. This concentrated solar-light is conveyed along a main direction perpendicular to the exit surface towards a single or multi-junction photovoltaic cell coupled to the waveguide via a secondary optical element. The multi-junction PV cell is customized to respond to the spectral light emerging from the waveguide as changed by the partial absorption through the optics that is molded of a plastic resin.

### CROSS-REFERENCE

This application is a continuation of U.S. patent application Ser. No. 13/053,184, filed Mar. 21, 2011 which claims the benefit of priority of U.S. Provisional Patent Application No. 61/315,744 filed Mar. 19, 2010; this application is a continuation-in-part of U.S. patent application Ser. No. 13/028,957, filed Feb. 16, 2011. Through the '957 Application, the present application is a continuation of U.S. patent application Ser. No. 13/007,910, filed Jan. 17, 2011, now U.S. Pat. No. 7,991,261. Through the '910 Application, the present application is a continuation of U.S. patent application Ser. No. 12/113,705, filed May 1, 2008, now U.S. Pat. No. 7,873,257. Through the '705 Application, the present application claims the benefit of priority of U.S. Provisional Patent Application No. 60/915,207 filed May 1, 2007; U.S. Provisional Patent Application No. 60/942,745 filed Jun. 8, 2007; and U.S. Provisional Patent Application No. 60/951,775 filed Jul. 25, 2007. Each of the foregoing applications is incorporated herein by reference in their entirety.

### FIELD OF THE INVENTION

The present invention relates to apparatuses for collecting, concentrating and harvesting solar-light by total internal reflection.

### DESCRIPTION OF THE RELATED ART

Concentrating Photovoltaic (CPV) solar panels are known and they are used to generate electricity for industrial and personal use.

Optical concentrators for photovoltaic (PV) solar applications are well known and they use reflective, refractive, diffractive, TIR waveguides, luminescence optics or combinations of these optical elements.

Optical concentrators using planar or slab waveguides in conjunction with collecting and focusing refractive optical elements have been used to improve the solar energy concentration onto reduced size PV cells to reduce the cost of the PV cell and to minimize the height of the solar panels.

There is a need to further optimize the design, the manufacturing and the assembling operations related to concentrating photovoltaic (CPV) solar panels based on planar or slab waveguides that use total internal reflection and the corresponding optical focusing elements. Both the optical efficiency and the overall efficiency that depends on the efficiency of the PV cells needs further refinements. The design of the optical components needs to be done also by considering the current and the future advances in the PV cells designs and manufacturing coupled to the waveguide optics.

### SUMMARY OF THE INVENTION

This invention discloses an optical solar concentrator having a focusing layer including focusing optical elements that concentrate sunlight onto the corresponding deflectors of a waveguide. The deflectors are located in the lower surface of the waveguide and in the focal plane of the focusing elements. The deflectors redirect the light inside the waveguide under total internal reflection conditions in order to collect the focused light and couple the sunlight to a photovoltaic cell. The sun light exiting from the waveguide is first redirected and further concentrated by a secondary optic that couple the light to the PV cell. The focusing optical elements and the deflectors are either longitudinal or annular and the PV cell is in several embodiments a multi-junction PV cell. The multi-junction cells have are designed for a spectral response that matches the spectrum of the light reaching the PV cell through the combined focusing elements, the waveguide and the secondary optical element.

The invention discloses several embodiments of the concentrators where the annular focusing elements and the annular deflectors have both circular and polygonal outer surfaces. The polygonal ouster surfaces allow for the better clustering of the optics to increase the active surface of the solar panels.

The invention also discloses a tray that that protects the optics and locates the PV cells relative to the optics. In some embodiments the material of the tray is similar to the material of the waveguide to allow the two parts to expand and shrink at the same rate during manufacturing and in the field and in the day and night conditions.

In some embodiments the tray is made of a polycarbonate that includes a carbon fiber filler to dissipate the heat from the PV cell. One such a material is Raheama made by Tejin Limited of Japan.

### BRIEF DESCRIPTION OF THE DRAWINGS

For a better understanding of the present invention, as well as other aspects and further features thereof, reference is made to the following description which is to be used in conjunction with the accompanying drawings, where:

FIG. 1 is a perspective exploded view of a solar-light concentration apparatus according to an embodiment of the invention;

FIG. 2 is a cross-sectional view of a photovoltaic solar-light concentration apparatus according to an embodiment of the invention with solar-light schematically shown by solid lines;

FIG. 3 is detail A of FIG. 2

FIG. 4 is a perspective view of the photovoltaic solar-light concentration apparatus of FIGS. 1,2,3 and 12 with the sun schematically shown and a trajectory of the sun during the course of a day shown in dotted lines;

FIG. 5 is a close-up view of the photovoltaic solar-light concentration apparatus of FIG. 2 shown having a focusing layer positioned off-set with respect to a waveguide;

FIG. 6 is a perspective view of a photovoltaic solar-light concentration apparatus according to another embodiment of the invention;

FIG. 7a is a cross-sectional view of the photovoltaic solar-light concentration apparatus of FIG. 6;

FIG. 7b is a cross-sectional view of another embodiment of a photovoltaic solar-light concentration apparatus having a cladding layer;

FIG. 8a is a perspective view of another embodiment of the photovoltaic solar-light concentration apparatus;

FIG. 8b is a cross section view of the secondary optic show in FIGS. 7a-b and FIG. 8a;

FIG. 9 a series of solar concentrators as shown in FIG. 8a, arranged in a string and also as a panel composed of strings;

FIG. 10 illustrates another embodiment of the invention showing of a string of photovoltaic concentrators;

FIG. 11 illustrates another embodiment of the invention showing a series of photovoltaic panels mounted on a dual axis;

FIG. 12 is a general view of a photovoltaic solar concentrator as shown in more details is FIGS. 2-3-4.

FIGS. 13a-b-c-d-e-f-g illustrate another embodiment of the invention showing a hexagonal shaped photovoltaic solar concentrator with a secondary optic.

### DETAILED DESCRIPTION OF THE PREFERRED EMBODIMENTS

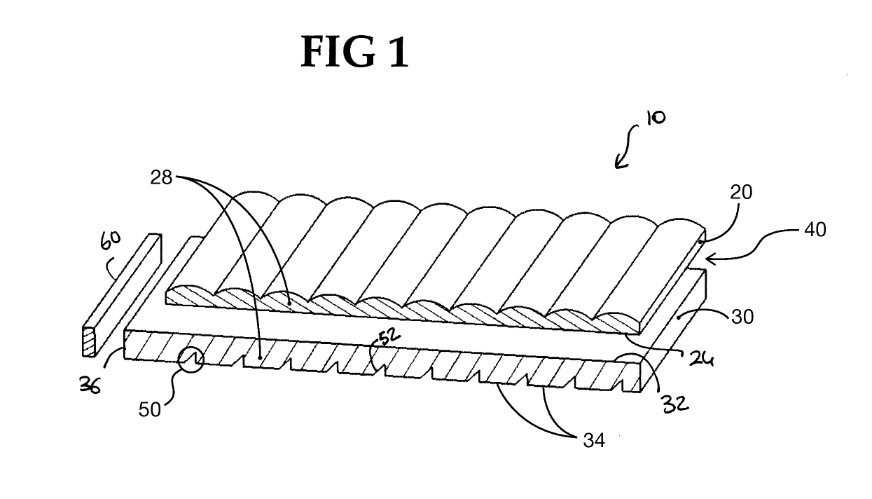

Referring to FIGS. 1 to 5, an embodiment of a photovoltaic solar-light concentration apparatus 10 will be described.

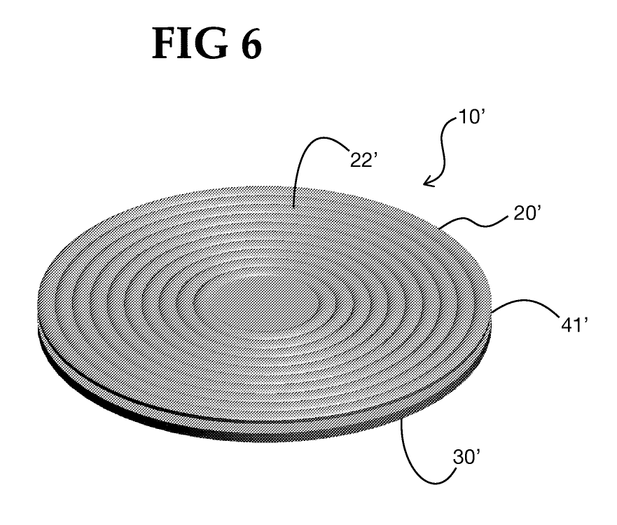

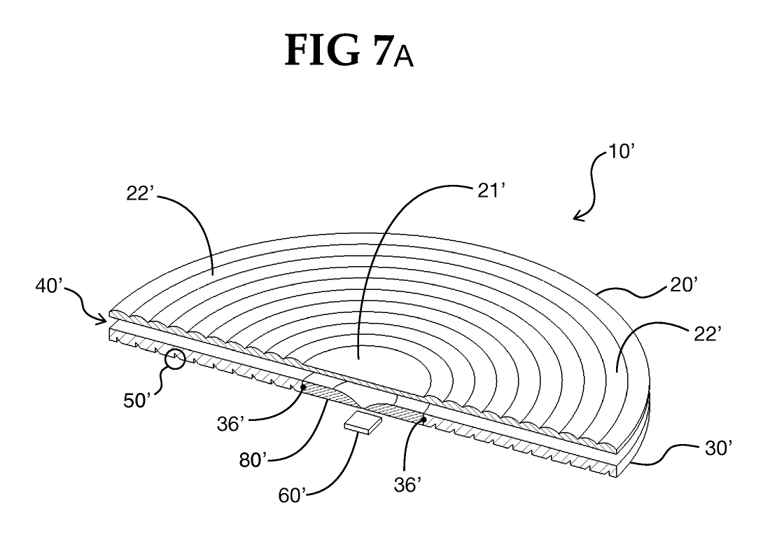

The photovoltaic solar-light concentration apparatus 10 is generally rectangular in shape. It is contemplated the focusing layer 20 and the waveguide 30 could be generally square. A second embodiment of a photovoltaic solar-light concentration apparatus 10′ having a generally circular shape will be described in greater detail below with reference to FIGS. 6 and 7.

The photovoltaic solar-light apparatus 10 comprises a focusing layer 20 and a waveguide 30 separated by an air gap 40. The focusing layer 20 and the waveguide 30 are generally rectangular. The focusing layer 20 and the waveguide 30 are parallel to each other.

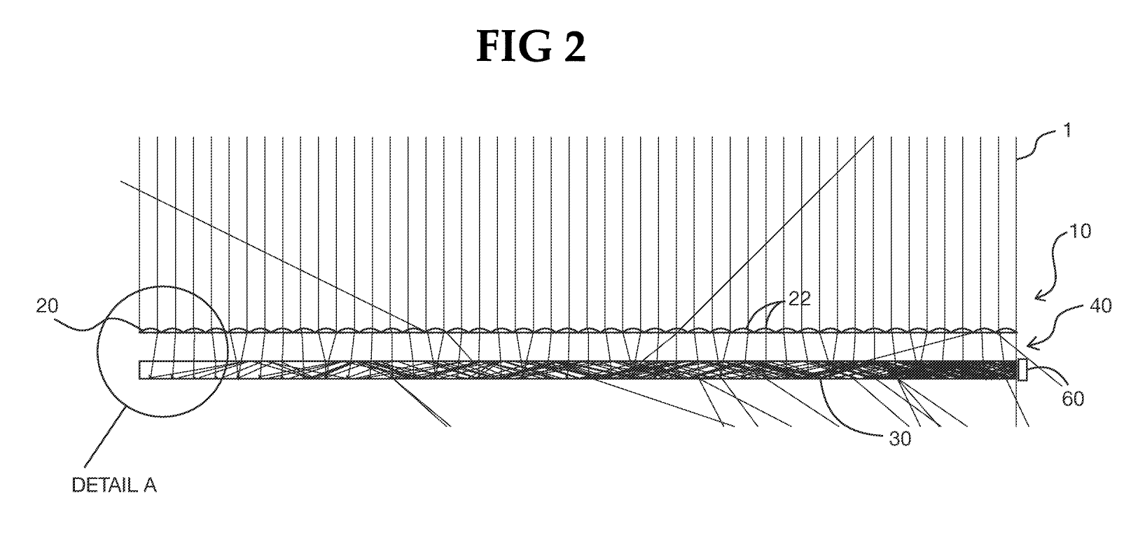

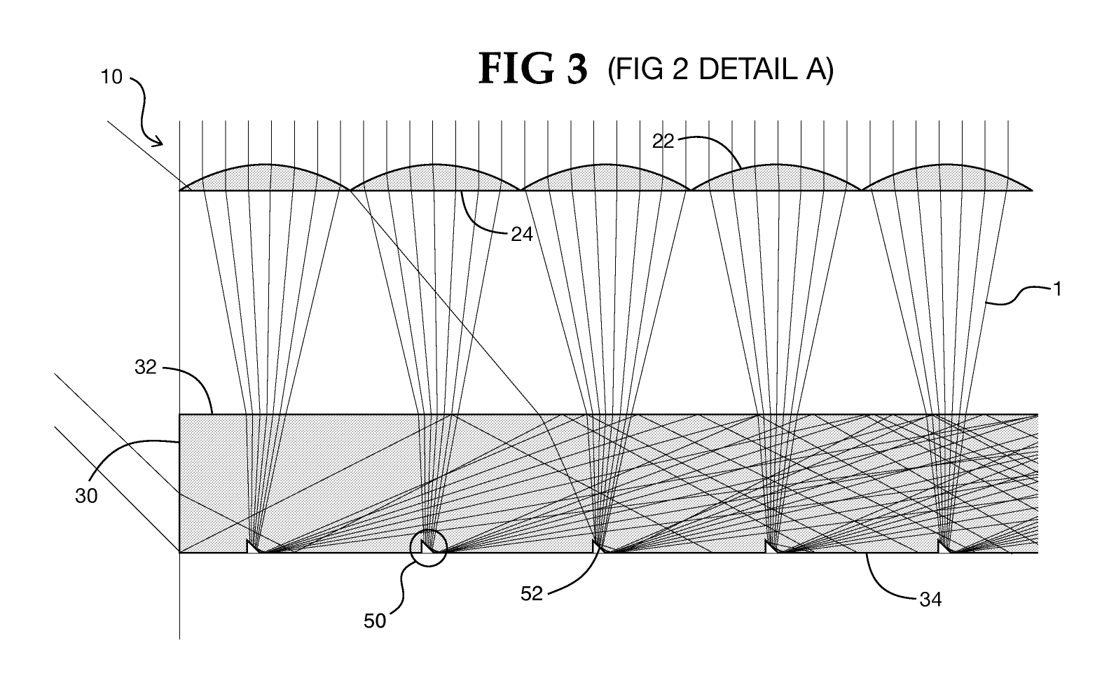

The focusing layer 20 comprises a plurality of longitudinal focusing elements 22 disposed an abutting side-by-side position. The plurality of longitudinal focusing elements 22 forms a plurality of stripes, wherein each stripe is a cylindrical lens. It is contemplated that the focusing elements 22 could be more elaborate and consists of various optical active facets of various shapes. Each focusing element 22 (i.e. stripe) collects concentrates (by focusing) solar-light 1 (shown in FIGS. 2 and 3) into a solar-light beam. The solar-light beam is narrower than a span of the solar-light 1 impacting the focusing element 22. The band of solar-light 1 exits the focusing layer 20 through a focussing side 24 of the focusing layer 20.

The waveguide 30 is a planar slab of acrylic glass. The waveguide 30 is injection molded. It is contemplated that the waveguide 30 could be thermoformed or injection molded from one or more moldable materials. For example, the waveguide 30 could be molded from optical grade polycarbonate, such as CALIBRE™, IUPILON™, LEXAN™, MAKROLIFE™ MAKROLON™, PANLITE™, TARFLON™ or LBE™. The waveguide 30 could also thermoformed or injection molded from polymethyl methacrylate (Plastic Materials) such as any of POLICRIL™, PLEXIGLAS™, GAVRIELI™, VITROFLEX™, LIMACRYL™, R-CAST™, PER-CLAX™, PERSPEX™, PLAZCRYL™, ACRYLEX™, ACRYLITE™, ACRYLPLAST™, ALTUGLAS™, POLYCAST™, OROGLASS™, OPTIX™, LUCITE™ and ACRYLIC™. The focusing layer 20 is made of the same materials and using the same manufacturing methods as the waveguide 30. Materials for the focusing layer 20 and the waveguide 30 are selected from same or different materials selected from the materials listed before.

The waveguide 30 is optically coupled to the focusing layer 20. The waveguide 30 has an entry surface 32 disposed facing the focussing side 24 of the focusing layer 20, a reflecting surface 34 opposite to the entry surface, and an exit surface 36 at an end of the entry surface 32 and the reflecting surface 34.

A plurality of longitudinal deflectors 50 is disposed on the reflecting surface 34. The plurality of longitudinal deflectors 50 is integrally formed with the waveguide 30 by injection molding. It is contemplated that the plurality of longitudinal deflectors 50 could be formed by injection compression molding. The longitudinal deflectors 50 are parallel to each other and parallel to the exit surface 36. The plurality of longitudinal deflectors 50 consists in a plurality of adjacent spaced apart stripes. It is contemplated that the deflectors 50 can be equally spaced or can be spaced at variable distances one relative to the other or in clusters. It is also contemplated that the stripes could not be spaced apart. Each longitudinal deflector 50 (i.e. stripe) has a shape of a wedge. It is contemplated that the longitudinal deflectors 50 could have more elaborate shapes than a single wedge.

The plurality of deflectors 50 is arranged in a one-to-one optical relationship with respect to the plurality of focusing elements 22. The plurality of deflectors 50 is positioned in the focal plane of the focusing elements 22 so that each deflector 50 receives the solar-light 1 coming from a single corresponding one focusing element 22. It is contemplated that, the plurality of deflectors 50 could not be positioned in the focal plane of the focusing elements 22. The deflectors 50 have a deflecting surface 52 positioned at an angle with respect to the incoming solar-light 1 beam so as to redirect the solar-light 1 into the waveguide 30 at an angle that ensures total internal reflection. It is contemplated that the deflecting surface 52 could be flat, segmented, multi-faceted or curved. It is also contemplated that the deflecting surface 52 could be mirror-coated or uncoated. It is also contemplated that the deflecting surface 52 could be sized and positioned with respect to the focusing elements 22 to always capture and deflect the entire solar-light beam 1 so that no focused light passes by the deflecting surface 52. This prevents direct focused light 1 not intercepted by surface 52 from escaping from the waveguide 30. It is contemplated that the waveguide 30 and thus the deflecting surface 52 could be slightly closer to the focusing element 22 (short focus) or a little further from the focusing element 22 (far focus) for as long as no light escapes the deflecting surface 52. Starting with this first reflection at the deflecting surface 52, the solar-light 1 is reflected between the entry surface 32 and the reflecting surface 34 at angles that exceed the critical angle (hence ensuring total internal reflection). The solar-light 1 is therefore trapped into the waveguide 30, and the total internal reflections direct unidirectionally the solar-light 1 toward the exit surface 36 of the waveguide. This combination of a longitudinal focusing element 22 and a longitudinal deflecting element 50 that together generate a band or stripe shaped solar beams 1 advancing via total internal reflection in the waveguide 30 allows for the optimum concentration since no solar light 1 will be directed towards the lateral walls/surface of the waveguide 30 to lower the amount of solar light 1 advancing towards the exit surface 36, that happens in some other known planar waveguides 30 for light concentration.

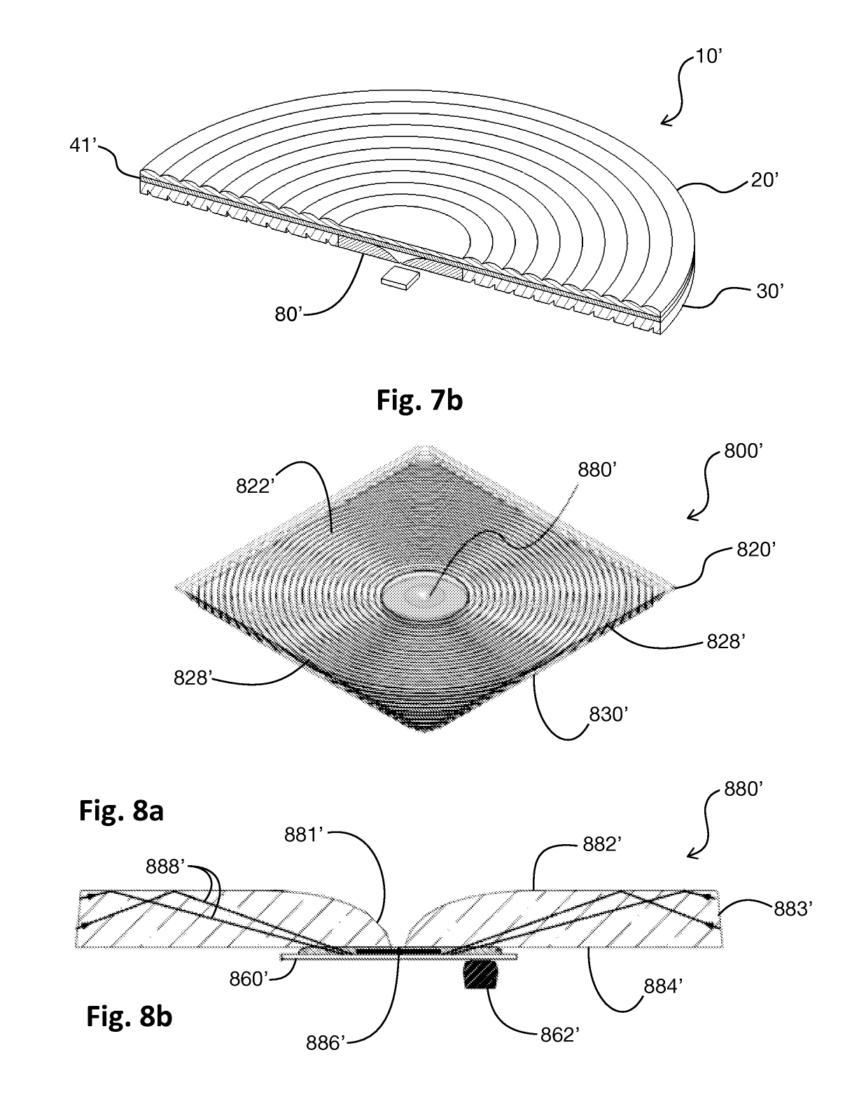

A photovoltaic (PV) cell 60 is optically coupled to the waveguide and is disposed at the exit surface 36 of the waveguide 30 and collects the solar-light 1 trapped in the waveguide 30. The photovoltaic cell 60 in FIGS. 1-2 is a single junction cell. It is contemplated that the photovoltaic cell 60 could be made of mono-crystalline or poly-crystalline Si, can be a multi-junction cell as shown in FIGS. 7-8-10 or a thin film. It is contemplated that the photovoltaic cell 60′ could be any multi-junction cell. It is contemplated that a secondary optic element 80′, as shown in FIGS. 7-8 could be optically coupled to waveguide 30′ to either change the direction of the solar beam exiting the waveguide 30′ or provide thermal insulation or additional focus/concentration of the solar beam 1 exiting the waveguide 30′ and reaching the photovoltaic cell 60′. The secondary optic 80′ can be a surface of the waveguide 30′ that is flat or curved and is angled to changes the direction of the solar beam travelling in the waveguide 30′ to reach the photovoltaic cell 60′ that is not co-linear with the solar beam traveling inside the waveguide 30′. The secondary optic can be also a separate element made of different optical material than the waveguide 30′ for higher concentration that increases the temperature of the waveguide towards to exit surface 36′, and can made of glass. The secondary optic 80′ being separated from the waveguide 30′ acts as a thermal buffer or barrier between the waveguide 30′ and the photovoltaic cell 60′ to also increase the efficiency of the photovoltaic cell 60′.

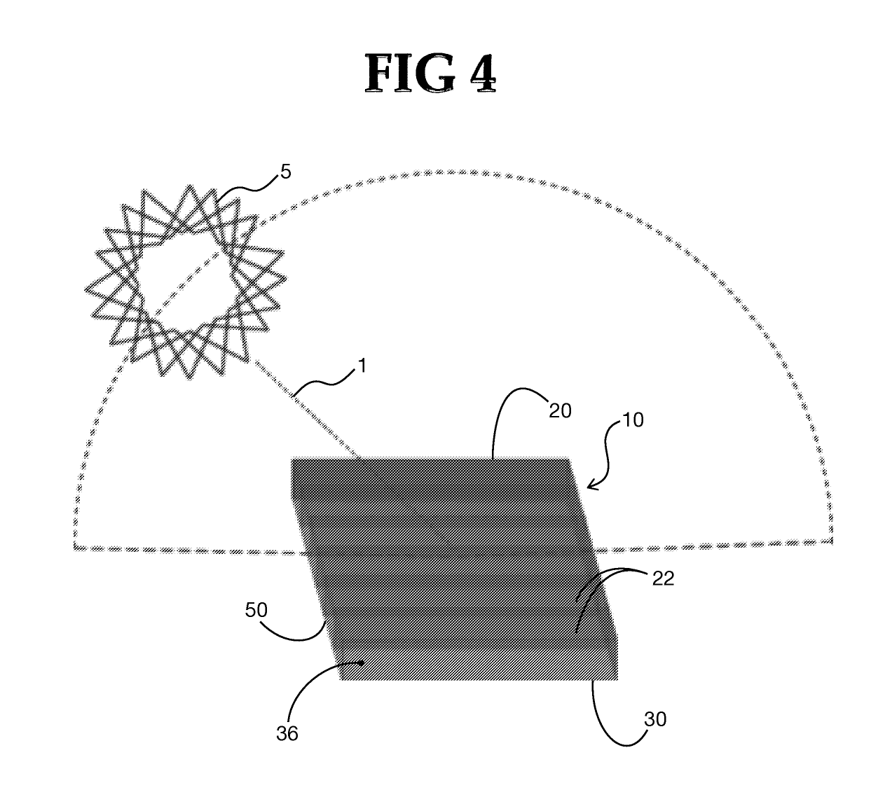

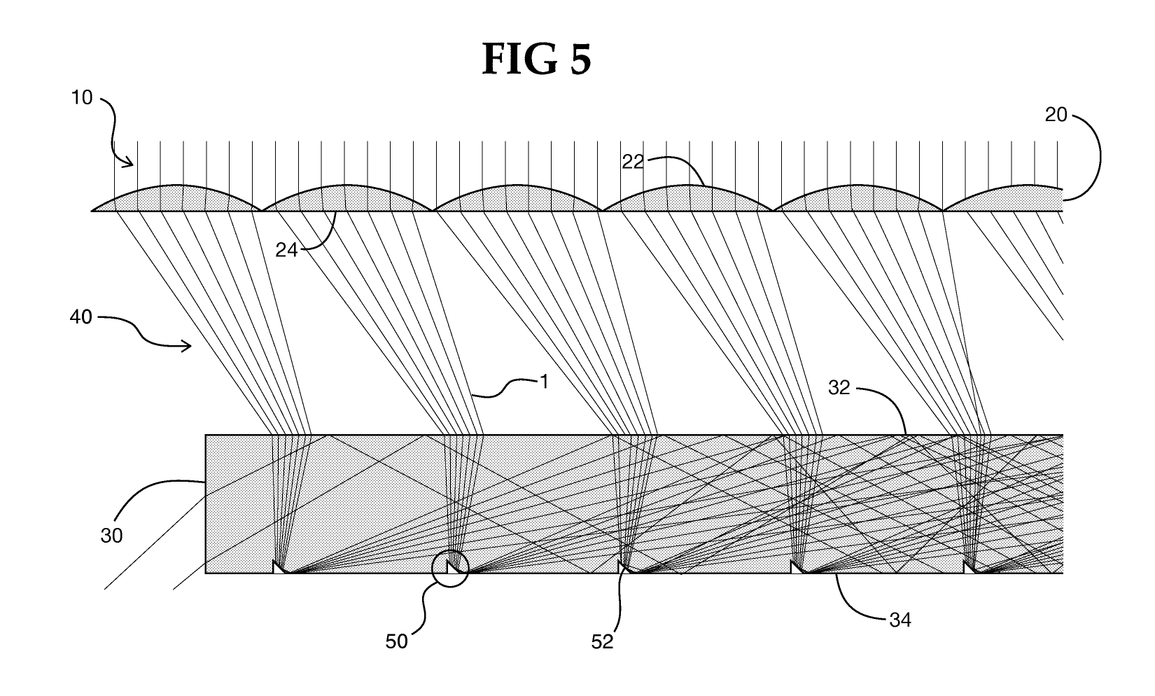

As best seen in FIG. 4, the solar-light concentration apparatus 10 can be positioned so as to track the solar-light 1 over the course of a year. This can be done by positioning the photovoltaic solar-light concentration apparatus 10 at different angles depending on the position of the sun 5 at noon-time over the year. Alternatively, as seen in FIG. 5, the focusing layer 20 can be positioned off-set of the waveguide 30. The shifting of position of the focusing layer 20 is adjusted during the year depending on the sun's 5 positions. Another way of accommodating the change in sun's 5 noon-time position is by introducing a prism in the air gap 40 for deflecting the solar-light 1 before the solar-light 1 enters the waveguide 30. The prism influences an angle of impact of the solar-light 1 onto the deflectors 50.

Referring now to FIGS. 6 to 8, the second embodiment of photovoltaic solar-light concentration apparatus 10′ will now be described. The photovoltaic solar-light concentration apparatus 10′ is similar in construction to the photovoltaic solar-light concentration apparatus 10, but differs in shape. Elements of the photovoltaic solar-light concentration apparatus 10′ common to the photovoltaic solar-light concentration apparatus 10 will be given the same reference numeral with a ′, and details of the common elements will not be repeated.

The photovoltaic solar-light concentration apparatus 10′ has a focusing layer 20′ and a waveguide 30′ separated by an air gap 40′. It is completed that the air gap 40′ could be replaced by a cladding layer 70′ (see FIG. 7B). The cladding layer 70′ can have a refractive index lower that the refractive index of the upper focusing layer and lower than that of the waveguide. The advantage of having such cladding layer 70′ is that it can protect the integrity of the concentrator in the field. The cladding layer 70′ can be made of any suitable material such as, for example, fluorinated ethylene propylene. The thickness of the cladding layer 70′can be relatively thin and still be effective. The focusing layer 20′ is disk-shaped, and comprises a plurality of focusing elements 22′ concentrically disposed in an abutting side-by-side relationship. The focusing elements 22′ are cylindrical lenses having an annular shape. A central portion 21′ of the focusing layer 20′ is deprived of focusing elements 22′.

The waveguide 30′ is disk-shaped and has the same size as the focusing layer 20′. The waveguide 30′ has an exit surface 36′ centrally located. The exit surface 36′ is positioned underneath the central portion 21′ of the focusing layer 20′ and has a radius of the central portion 21′.

The waveguide 30′ has a plurality of deflectors 50′ disposed on a reflecting surface 34′ of the waveguide 30′. The plurality of deflectors 50′ consists in annular wedges disposed concentrically. The deflectors 50′ are isolated with respect to each other. The plurality of deflectors 50′ is disposed in the waveguide 30′ so as to create a one-to-one relationship with the plurality of focusing elements 22′. Similarly to the solar-light concentration apparatus 10, the solar-light 1 is trapped into the waveguide 30′ and is directed unidirectional by total internal reflection toward the exit surface 36′.

A secondary optic 80′ is disposed at the exit surface 36′. The secondary optic 80′ is disk-shaped. The secondary optic 80′ directs and concentration the solar-light 1 coming radially from the exit surface 36′ into a spot. It is contemplated that the secondary optic 80′ could be omitted.

A photovoltaic cell 60′ is disposed underneath a center of the secondary optic 80′. The photovoltaic cell 60′ has a square shaped active area. It contemplated that photovoltaic cell 60′ could be circular.

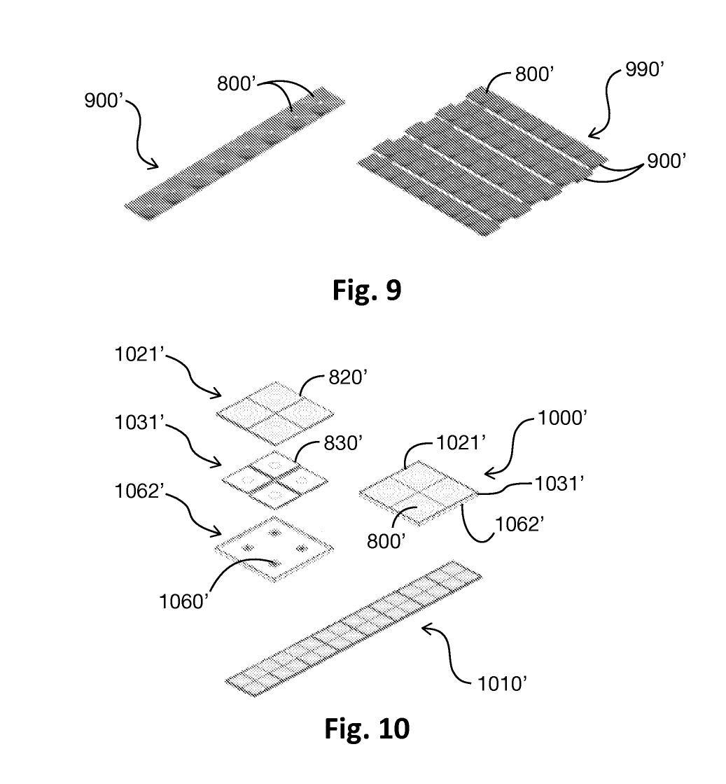

FIGS. 8a and 8b show a photovoltaic concentrator (800′) having a focusing layer (820′) with annular and concentric focusing elements (822′) and a planar slab waveguide (830′) having deflecting elements (850′) not shown but similar to item (50′) of FIG. 7a, concentrator (800′) having a square or rectangular shape (top view) that is useful for assembling a string (900′) of concentrators to make a PV solar concentration panel (990′) both shown in FIG. 9. This concentrator 800′ is square or rectangular shaped (four faces polygon) having lateral surfaces (828′) and having in the center a disc shaped secondary optic (880′) element to redirect and further concentrate the light onto a multi-junction PV cell (860′) show in FIG. 8b.

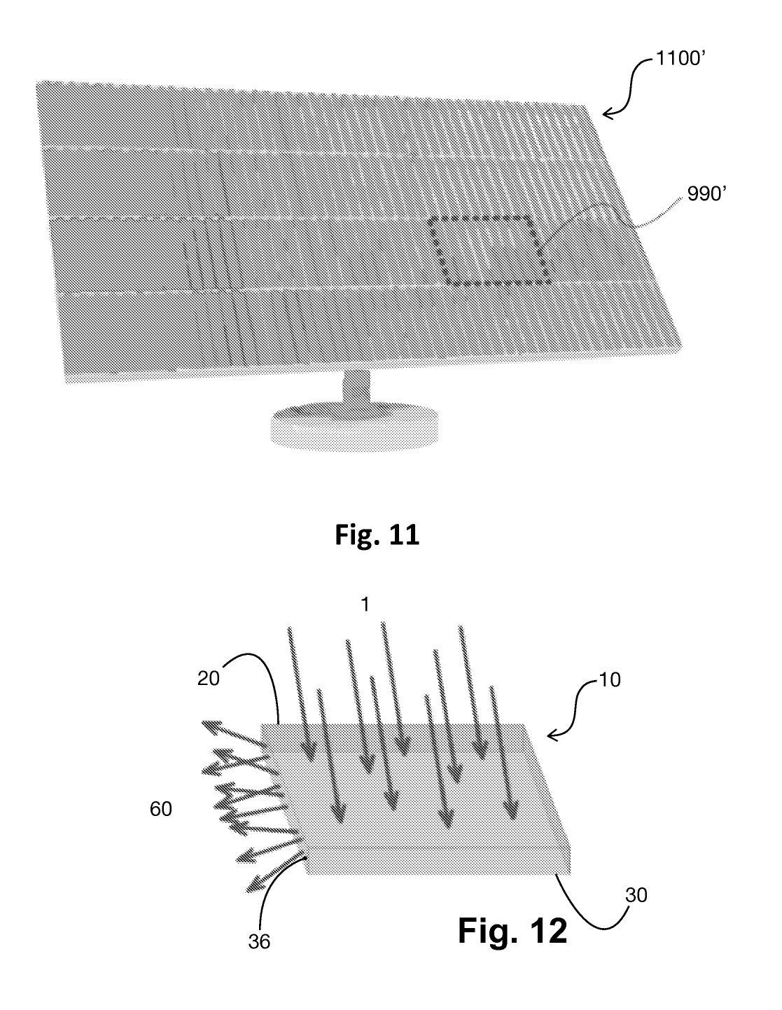

FIG. 10 shows a blown up detail of an assembly (1000′) of four concentrators (800′) including a top layer (1021′) made of four coplanar focusing layer elements (820′), a middle layer made of four coplanar waveguide elements (830′) and a base layer or a tray (1062′) wherein the tray holds and aligns four multi-junction PV cells (1060′) onto which the concentrators (800′) direct the light.

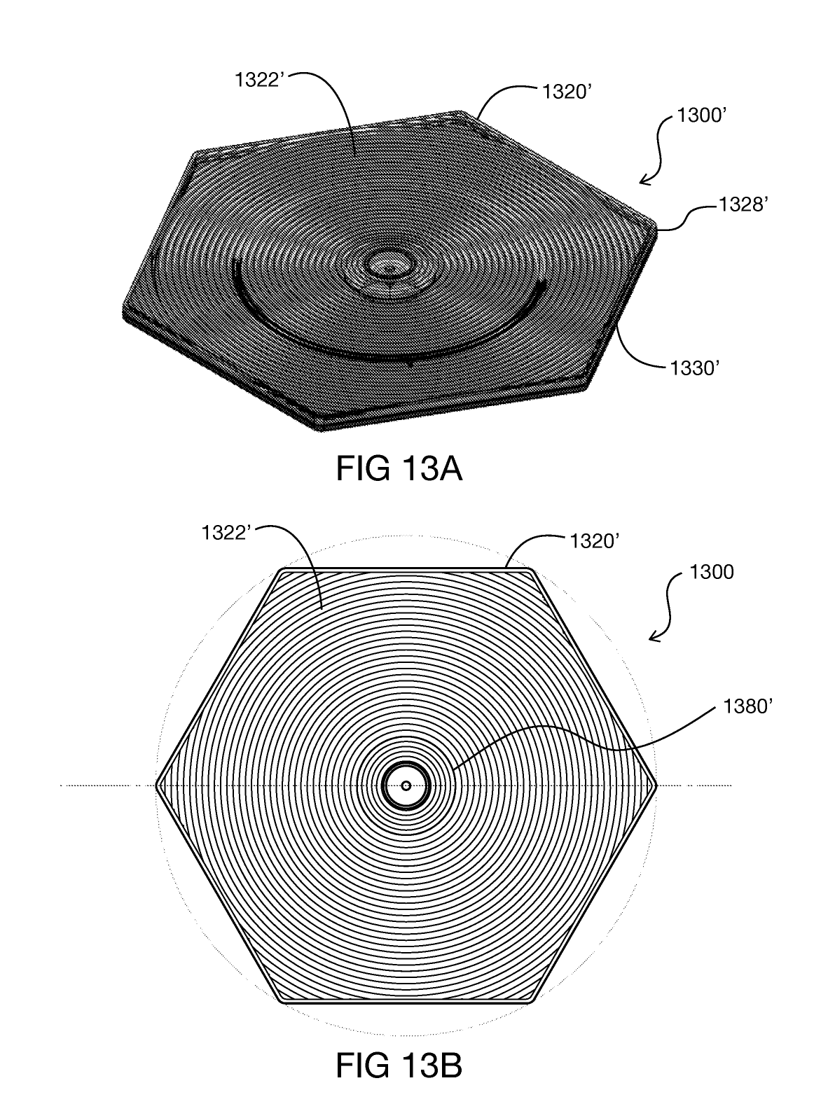

FIG. 11 shows a series (1100′) of solar panels (990′) on a dual axis solar tracker.

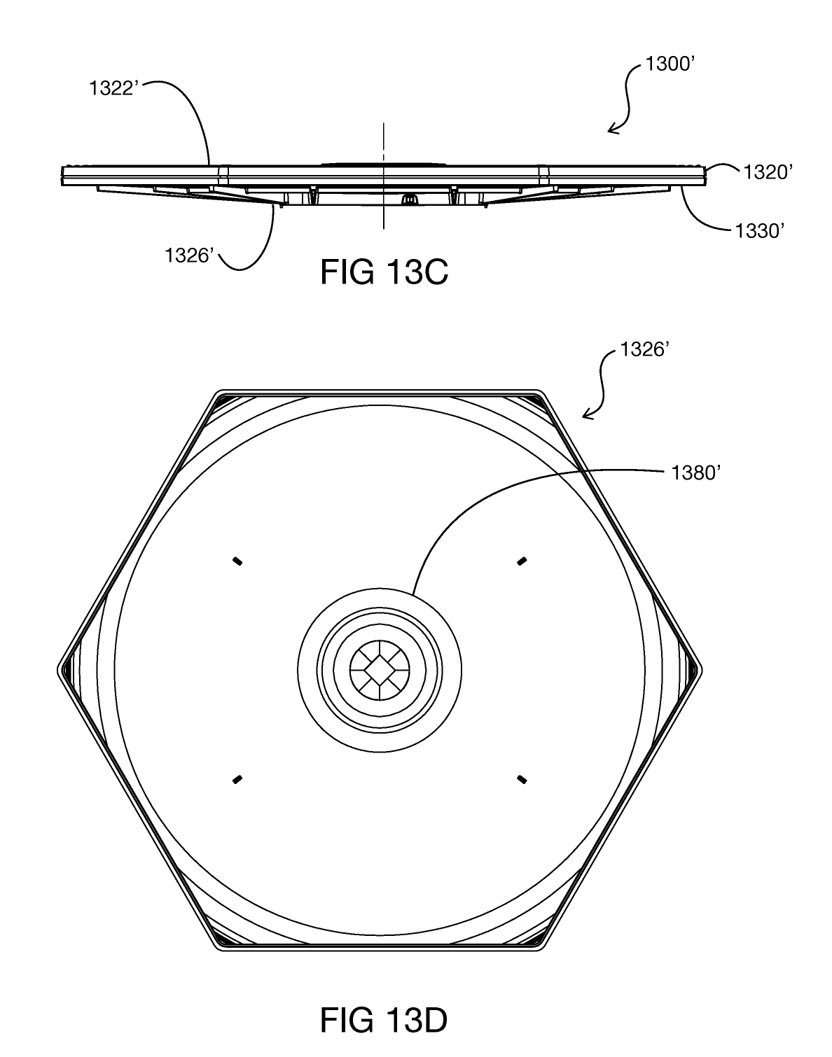

FIG. 12 is a general view of solar concentrator (10) as shown in more details is FIGS. 2-3-4. Solar concentrator (10) includes a focusing layer (20) and a waveguide (30) that collect, focus and direct the sunlight (1) through an exit surface (36) towards a PV cell (60).

Referring back to FIGS. 1-13 they show several embodiments of solar-light concentration apparatus several embodiments of solar-light concentration apparatus according to this invention.

Referring to FIGS. 1-5 they show some of the several embodiments of solar-light concentration apparatus (10) having a focusing layer (20) with longitudinal focusing elements (22) and a waveguide (30) having longitudinal deflectors (50) and a multi-junction PV cell (60).

Referring to FIGS. 5-13 they show some of the several embodiments of a revolved solar-light concentration apparatus (10′/800′/1300′) having a focusing layer (20′/820′/1320′) with annular focusing elements (22′/822′/1322′) and a waveguide (30′/830′/1330′) having annular deflectors similar to (50′) shown 7a, a secondary optic (80′/880′/1380′) and a multi-junction PV cell (60′/860′/1360′).

General comparison of concentrations for revolved and linear geometries for the concentrator of the current invention.

The formula for geometrical concentration is:

$$C = \frac{{A}_{c}}{{A}_{a}}$$

here C is the geometrical concentration factor of the revolved geometry, A_{c} is the sun collection area and Aₐ is the energy absorber area.

For the revolved and linear geometries, the collection area is the same. What differs is the area of the absorber.

For the linear geometry, the area of the absorber is equal to

Aₐ=h·l

where l is the length of the linear focusing elements.

For the revolved geometry, the area of the absorber is equal to

Aₐ=2πr_{centre}h

where r_{centre} is the radius of hole at the centre of the optics and h is the height of the waveguide.

For the case where r_{centre}=20 mm, h=4 mm and l=200 mm, the revolved geometry has a concentration factor which is approximately 1.6 times the concentration of the linear geometry.

With numbers:

Therefore, for a collection area of approximately A_{c}=314 cm², and the parameters as specified above, we have the following:

### Revolved Geometry

The concentration factor of the revolved geometry is 62.5 for the above scenario. Further concentration can be added by using a secondary optic with an additional concentration factor of 1.5. This increases the total concentration for the revolved optic to 93.75. With this concentration, a multi-junction pv cell at 40% efficiency can be used which has an area of 3.3 cm².

### Linear Geometry

The concentration factor of the linear geometry is approximately 39.3 for the above scenario. Since the absorber area of the linear geometry is very large (8 cm² in this scenario), a PV cell with efficiency of 8% will have to be used, since multi-junction cells are too expensive to used to cover that much area.

The increased concentration of the revolved geometry in combination with the secondary optic and the possibility to use a multi-junction cell makes the revolved geometry a much more attractive design than the linear geometry. Also the fact that the deflection elements and the focusing elements can be diamond turned more efficiently makes the revolved geometry more attractive for higher concentration in many applications.

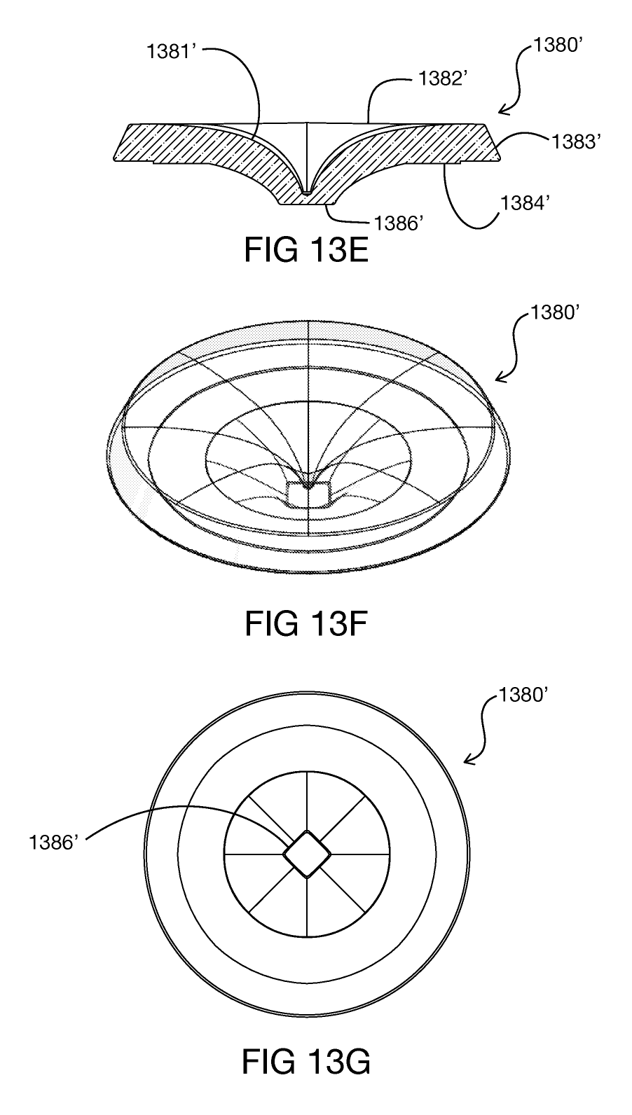

In particular, FIG. 8a and FIG. 13 show the solar-light concentration apparatus (800′/1300′) having a planar focusing layer (820′/1320′) with a regular polygonal entry surface facing impinging sunlight (1) and including a plurality of annular focusing elements (822′/1322′) disposed along concentric circles. The solar-light exiting each of the plurality of annular focusing elements (822′/1322′) is an annular band of solar-light. The focusing layer (820′/1320′) is injection molded of poly-methyl methacrylate or other thermoplastic materials and forms a planar slab of a certain thickness.

The spectrum of the sunlight entering the focusing layer is partially absorbed by the poly-methyl methacrylate (or other materials) therefore altering the spectrum of the exiting light and this impacts the performance of the system since it requires a customized multi-junction PV cell. A planar waveguide ( ) slab is optically coupled to the focusing layer having a regular polygonal shape and an optically smooth flat upper surface ( ) and an opposed lower flat surface having a corresponding regular polygonal shape. The lower surface ( ) is parallel to the upper surface ( ) to create a waveguide of a constant thickness. Both surfaces are bare, that is they don't have any type of mirror coating to reduce the cost and the damage that can be caused in operation due to sun exposure or the humidity that will lower the reflections inside the waveguide.

The waveguide ( ) is separated from the focusing layer ( ) by a material having a lower index of refraction than the waveguide ( ). In this embodiment the waveguide has an annular-exit surface ( ) and a plurality of annular deflecting elements ( ) each located in the focal plane of a corresponding focusing element and along concentric circles on the lower surface of the waveguide. By placing the deflecting elements on the lower surface of the waveguide the optical coupling with the focusing elements is improved and less light escape through the waveguide. The annular deflecting elements are disposed to deflect the focused solar at an angle that causes total internal reflection of the solar-light inside the waveguide, the solar-light being conveyed toward the exit surface of the waveguide by multiple total internal reflections between the parallel upper and lower surfaces of the waveguide that are not mirror coated. The waveguide layer is molded of poly-methyl methacrylate or other moldable material. The spectrum of the sunlight entering the waveguide ( ) is partially absorbed by the poly-methyl methacrylate (or other materials) therefore further altering the spectrum of the light exiting the waveguide and this impacts the performance of the concentrating system since it requires a customized multi-junction PV cell responsive to this changed solar spectrum.

Because of the increased demand for high solar efficiency for a reduced foot print this invention shows the coupling of the waveguide optics to multi-junction cells that are not only smaller in size to increase the optical concentration but also they are more efficient and more flexible to be made for a specific and more customized input solar spectrum affected by the absorption caused by the focusing elements and the waveguide that are made of moldable plastic resins. Also the lengthy travel of the light trough the waveguide contributes to a larger spectrum absorption in the waveguide than in the focusing layer. A multi junction photovoltaic cell is disposed to receive the solar light emerging from the waveguide and the multi-junction PV cell is designed to provide an optimum electronic efficiency for the sunlight spectrum exiting the waveguide.

In some embodiments of the invention a disc shaped secondary optical element ( ) having an annular entry surface ( ) and a reflecting surface ( ) is located between the waveguide and the multi-junction PV cell as shown in FIG. 13. The secondary optical element is disposed to couple the solar light from the waveguide onto the photovoltaic cell by deflection from the reflecting surface ( ). The secondary optical element ( ) is made of glass, preferably a high refractive index optical glass. The spectrum of the sunlight exiting the secondary optical element is also changed by any absorption in the secondary optical element.

As shown in FIG. 13c a tray is used under the waveguide to retain the waveguide and the focusing layer and to further position the secondary optic and/or the PV cell. The tray is molded of a material that ideally has the same thermal expansion as the waveguide and or the focusing layer. In higher concentration applications the tray is made of a conductive polymer such as for example Raheama made by Teiji Japan.

Raheama consists of 50-200 micrometer fibers cut from a cylindrical graphite fiber stock measuring about 8 micrometers in diameter. It disperses well in plastic, allowing manufacturers to produce heat-radiation components of almost any shape. Raheama's thermal expansion coefficient is as low as that of ceramics, so compacts created with the material have exceptional dimensional stability. Raheama also offers high electrical conductivity, making it suitable for the prevention of static and shielding from radio waves.

Raheama has two standard specifications, R-A201 and R-A301, each boasting its own set of special features. R-A201 offers superior moldability and dispersion as a filler in plastic or rubber. It also combines with other fillers. R-A301 provides superior heat radiation, ranging from high levels of thermal conductivity using just small amounts of filler to extra-high levels as more filler is added.

Table with some of the item numbers.

| Item # | Item |
|---|---|
| 1 | Solar light |
| 5 | The sun |
| 10 | Photovoltaic solar light concentraion apparatus |
| 20 | Focusing layer |
| 22 | Longitudinal focusing elements |
| 24 | Focusing surface of the focusing layer |
| 30 | Waveguide with longitudinal deflectors |
| 32 | Entry surface of the waveguide |
| 34 | Reflecting surface of the waveguide |
| 36 | Exit surface of the waveguide |
| 40 | Air gap |
| 50 | Longitudinal deflectors |
| 52 | Deflecting surface of the deflector |
| 60 | Multi-junction photovoltaic cell |
| 10′ | Second embodiment of photovoltaic solar-light |
| | concentration apparatus |
| 20′ | Focusing layer |
| 21′ | Central portion of the focusing layer |
| 22′ | Annular Focusing elements |
| 30′ | Waveguide with annular deflectors |
| 34′ | Reflecting surface of the waveguide |
| 36′ | Exit surface of waveguide |
| 40′ | Air gap |
| 41′ | Cladding |
| 50′ | Deflectors of waveguide |
| 60′ | Multi-junction photovoltaic cell |
| 70′ | Cladding layer to replace air gap |
| 80′ | Secondary optic |
| 800′ | Solar concentration apparatus |
| 820′ | Focusing layer |
| 822′ | Annular Focusing element |
| 824′ | Lateral Surface |
| 830′ | Waveguide with annular deflectors |
| 860′ | Multi-junction photovoltaic cell |
| 662′ | Bypass diode |
| 880′ | Secondary optic |
| 881′ | Reflecting surface |
| 882′ | Top surface of secondary optic |
| 883′ | Entry surface of the secondary optic |
| 884′ | Lower surface of the secondary optic |
| 886′ | Exit surface of the secondary optic |
| 900′ | String of concentrators |
| 990′ | Solar Panel |
| 1000′ | Matrix of concentrators |
| 1010′ | String of concentrators |
| 1021′ | Focusing layer |
| 1031′ | Waveguide |
| 1060′ | Multi-junction photovoltaic cell |
| 1062′ | Concentrator tray |
| 1300′ | Solar concentration apparatus |
| 1320′ | Focusing layer |
| 1322′ | Annular Focusing Element |
| 1326′ | Tray |
| 1328′ | Lateral Surface |
| 1330′ | Waveguide with annular deflectors |
| 1360′ | Multijunction photovoltaic cell |
| 1380′ | Secondary Optic |
| 1381′ | Reflecting surface |
| 1382′ | Top surface of secondary optic |
| 1383′ | Entry surface of secondary optic |
| 1384′ | Lower surface of secondary optic |
| 1386′ | Exit surface of the secondary optic |

Modifications and improvements to the above-described embodiments of the present invention may become apparent to those skilled in the art. The foregoing description is intended to be exemplary rather than limiting. The scope of the present invention is therefore intended to be limited solely by the scope of the appended claims.

1-5. (canceled)

6. A system for capturing solar energy, the system comprising:
a first lens array having a plurality of lenses;
a first waveguide component adjacent to the lens array, wherein the waveguide component receives light, and wherein the waveguide component includes an array of prism facets arranged along at least one surface of the waveguide component; and
at least one photovoltaic cell positioned so as to receive at least a portion of the light that is directed out of the waveguide;
wherein at least some of the light passing into the waveguide component is restricted from leaving the waveguide component upon being reflected by at least one of the prism facets, and
whereby the at least some light restricted from leaving the waveguide component is directed by the waveguide toward the at least one photovoltaic cell.

7. The system of claim 6, wherein the at least some light is substantially trapped within the waveguide by total internal reflection due to operation of the prism facets.

8. The system of claim 6, wherein each of the prism facets is aligned with a respective one of the lenses of the lens array.

9. The system of claim 6, wherein the lens array includes an outer surface upon which the light received by the waveguide is initially incident prior to being received by the waveguide, and an inner surface opposed to the outer surface, the inner surface extending alongside the waveguide component.

10. The system of claim 9, wherein the lenses of the lens array serve to focus the light toward the prism facets of the waveguide component.

11. The system of claim 9, wherein the waveguide component includes a first surface, a second surface and an intermediate light conductive structure in between the first and second surfaces, wherein a cladding layer forms the first surface and the cladding layer is in contact with the inner surface of the lens array.

12. The system of claim 11, wherein the prism facets are formed along the second surface.

13. The system of claim 6, wherein at least two portions of the system are capable of being shifted relative to one another so that incident light first arriving at the system is ultimately received by the prism facets even though the incident light varies with time in terms of an angle of incidence.

14. The system of claim 6, wherein the waveguide component is laterally shiftable relative to the lens array.

15. The system of claim 6, wherein the waveguide component receives the light from the lens array after the light has previously arrived at the lens array.

16. The system of claim 15, wherein the light arrives at the lens array from an external location.

17. The system of claim 6, wherein a first of the at least one photovoltaic cell is positioned along a longitudinal edge of the waveguide component.

18. The system of claim 6, further comprising one or more of a folding prism, a curved mirror, and a reflector positioned along at least one longitudinal edge of the waveguide component.

19. The system of claim 18, wherein the at least some of the light directed toward the at least one photovoltaic cell proceeds to the at least one photovoltaic cell only after being redirected by one or more of the folding prism, the curved mirror, and the reflector.

20. The system of claim 19, wherein a first of the at least one photovoltaic cell also receives additional light from another adjacent waveguide component.

21. A planar array solar energy system including the system of claim 19 and further including a plurality of additional systems each including a respective waveguide component and a respective lens array.

22. The system of claim 6, wherein a first portion of the at least some light restricted from leaving the waveguide component is directed by the waveguide component to and through a first edge surface of the waveguide component and thereby coupled into a first of the at least one photovoltaic cell.

23. The system of claim 6,
wherein the first waveguide component includes first and second longitudinal surfaces that are substantially opposed to one another, wherein the first longitudinal surface extends alongside the lens array,
wherein the waveguide component further includes first and second side edge surfaces each extending between the first and second longitudinal surfaces and further extending away from the lens array, and
wherein the waveguide component further includes first and second end edge surfaces each extending between the longitudinal surfaces and also between the side edge surfaces.

24. The system of claim 6, wherein each of the prism facets is configured to direct at least a portion of the light in a respective direction within the waveguide component.

25. The system of claim 24, wherein the prism facets are respectively configured to direct the at least some light toward the at least one photovoltaic cell.

26. The system of claim 25, wherein the prism facets are respectively configured to direct at least some light in a radial manner toward the at least one photovoltaic cell, and wherein the at least one photovoltaic cell is positioned at a location other than an edge surface of the waveguide.

27. The system of claim 26, wherein the waveguide component is either cylindrical or hexagonal.

28. A method of capturing solar energy, the method comprising:
receiving light at a waveguide component;
reflecting at least a portion of the received light at a plurality of prism facets formed along a surface of the waveguide component, wherein substantially all of the reflected light experiences total internal reflection within the waveguide component subsequent to being reflected by the prism facets;
communicating the reflected light within the waveguide component toward an edge surface of the waveguide layer; and
receiving the communicated reflected light at a photovoltaic cell upon the communicated reflected light being transmitted through the edge surface.

29. The method of claim 28, wherein the photovoltaic cell extends substantially between the first and second surfaces of the waveguide layer.

30. The method of claim 28, wherein the light is first provided to a plurality of lenses and then subsequently transmitted to a cladding layer of the waveguide component by which the light is received by the waveguide component, the received light then proceeding through a waveguide layer of the waveguide component.

31. The method of claim 28, wherein either the prism facets, or at least one optical path to the prism facets, is modified in at least one characteristic over time as changes in the light occur.
